(19) United States
(12) Patent Application Publication
(10) Pub. No.: US 2021/0332281 A1
(43) Pub. Date: Oct. 28, 2021

(54) HEAT RADIATION MATERIAL, METHOD FOR PRODUCING HEAT RADIATION MATERIAL, HEAT RADIATION MATERIAL KIT, AND HEAT GENERATOR

(71) Applicant: Showa Denko Materials Co., Ltd., Tokyo (JP)

(72) Inventors: Maki TAKAHASHI, Chiyoda-ku, Tokyo (JP); Takashi ANDOU, Chiyoda-ku, Tokyo (JP); Yoshitaka TAKEZAWA, Chiyoda-ku, Tokyo (JP); Takanobu KOBAYASHI, Chiyoda-ku, Tokyo (JP); Naoki MARUYAMA, Chiyoda-ku, Tokyo (JP)

(73) Assignee: Showa Denko Materials Co., Ltd., Tokyo (JP)

(21) Appl. No.: 17/281,997

(22) PCT Filed: Sep. 11, 2019
(86) PCT No.: PCT/JP2019/035748

§ 371 Date: Apr. 1, 2021

(30) Foreign Application Priority Data
Oct. 4, 2018 (JP) PCT/JP2018/037247

(51) Int. Cl. C09K 5/14; F28F 21/08; C23C 24/00; B32B 37/24

(52) U.S. Cl. CPC C09K 5/14; F28F 21/089; H01L 23/3737; B32B 37/24; C23C 24/00

(57) ABSTRACT

A heat radiation material which includes metal particles and a resin and has a region inside where the metal particles arranged along the surface direction are present in a relatively high density.

### TECHNICAL FIELD

The present invention relates to a heat radiation material, a method for producing a heat radiation material, a heat radiation material kit, and a heat generator.

### BACKGROUND ART

In recent years, the amount of heat generated per unit area has tended to increase with reduction in size and an increase in the number of functions of electronic equipment. As a result, heat spots on which heat is locally concentrated are generated in electronic equipment, which causes problems such as a failure of the electronic equipment, a reduction in lifespan, a deterioration of operation stability, and a deterioration of reliability. For this reason, it is becoming increasingly important to radiate heat generated by a heat generator to the outside to alleviate the generation of heat spots.

As measures for heat radiation from electronic equipment, a heat radiator such as a metal plate or a heat sink is attached to the vicinity of a heat generator of the electronic equipment to conduct heat generated by the heat generator to the heat radiator and radiate heat to the outside. However, it may be difficult to attach a heat radiator to electronic equipment due to the reduction in size of electronic equipment. Consequently, a sheet-like heat radiation material has been examined as heat radiating means adaptable to reduction in size of electronic equipment.

For example, Patent Literature 1 discloses a heat radiation material in which a coating film obtained by dispersing a heat conductive filler in a silicone resin is formed on a heat radiating sheet layer. However, in a case where such a heat radiation material is disposed in the vicinity of electronic equipment covered with a resin member such as a resin case, most of the infrared light radiated from the heat radiation material is absorbed without passing through the resin member. As a result, new heat spots are generated in the resin member, and thus there is a concern that a sufficient radiative heat transfer effect may not be obtained.

### REFERENCE LIST

### Patent Literature

Patent Literature 1: Japanese Patent Laid-Open No. 2011-222862

### SUMMARY

### Technical Problem

In view of the above-described circumstances, an objective of an aspect of the present invention is to provide a heat radiation material which is capable of efficiently radiating and transferring heat generated by a heat generator, and a method for producing the same. An objective of another aspect of the present invention is to provide a heat radiation material kit for producing the heat radiation material and a heat generator including the heat radiation material.

### Solution to Problem

Means for solving the above-described problems include the following embodiments.

<1> A heat radiation material including metal particles and a resin, in which a region in which the metal particles arranged in a surface direction are present at a relatively high density is provided inside the heat radiation material.

<2> The heat radiation material according to <1>, in which a proportion of the metal particles in an observation surface is 50% or more on an area basis when the region is observed from in front.

<3> The heat radiation material according to <1> or <2>, in which the region has a function of changing an absorption wavelength spectrum of the heat radiation material which is measured using a Fourier transform infrared spectrophotometer.

<4> The heat radiation material according to any one of <1> to <3>, in which the region is provided at the center in a thickness direction of the heat radiation material.

<5> The heat radiation material according to any one of <1> to <3>, in which the region is provided close to a side of a surface facing a heat generator.

<6> The heat radiation material according to any one of <1> to <3>, in which the region is provided close to a side of a surface opposite to a surface facing a heat generator.

<7> The heat radiation material according to any one of <1> to <6>, in which a thickness of the region is in a range of 0.1 μm to 100 μm.

<8> The heat radiation material according to any one of <1> to <7>, in which a ratio of a thickness of the region to a whole thickness of the heat radiation material is in a range of 0.1% to 99%.

<9> The heat radiation material according to any one of <1> to <9>, in which the region has an uneven structure derived from the metal particles on a surface thereof.

<10> The heat radiation material according to any one of <1> to <10>, in which a region 1, a region 2, and a region 3 are provided in this order. The region 1, the region 2, and the region 3 are satisfying the following (A) and (B):

(A) a total value of absorption of electromagnetic waves at wavelengths of 2 μm to 6 μm in the region 2>a total value of absorption of electromagnetic waves at wavelengths of 2 μm to 6 μm in the region 1 and the region 3, and

(B) a metal particle occupancy rate in the region 2>metal particle occupancy rates in the region 1 and the region 3.

<11> A method for producing a heat radiation material which includes the following steps in the following order, the steps including a step of disposing metal particles on a first resin layer, and a step of disposing a second resin layer on the metal particles.

<12> A heat radiation material kit which is used to produce the heat radiation material according to any one of <1> to 10>, the heat radiation material kit including metal particles and a resin.

<13> A heat generator including the heat radiation material according to any one of <1> to <11>.

### Advantageous Effects of Invention

According to an aspect of the present invention, a heat radiation material which is capable of efficiently radiating and transferring heat generated by a heat generator are provided and a method for producing the same. According to another aspect of the present invention, a heat radiation material kit for producing the heat radiation material and a heat generator including the heat radiation material are provided.

### BRIEF DESCRIPTION OF THE DRAWINGS

FIG. 1 is a schematic cross-sectional view of a sample manufactured in Example 1.

FIG. 2 is a schematic cross-sectional view of a sample manufactured in Example 2.

FIG. 3 is a schematic cross-sectional view of a sample manufactured in Example 3.

FIG. 4 is a schematic cross-sectional view of a sample manufactured in Comparative Example 3.

FIG. 5 shows an absorption wavelength spectrum of the sample manufactured in Example 1.

FIG. 6 shows an absorption wavelength spectrum of a sample manufactured in Comparative Example 1.

FIG. 7 shows an absorption wavelength spectrum of a sample manufactured in Comparative Example 2.

FIG. 8 is a schematic cross-sectional view of electronic equipment manufactured in Example 7.

FIG. 9 is a schematic cross-sectional view of electronic equipment manufactured in Example 8.

FIG. 10 is a schematic cross-sectional view of a heat pipe manufactured in Example 9.

### DESCRIPTION OF THE EMBODIMENTS

Hereinafter, a mode for carrying out the present invention will be described in detail. However, the present invention is not limited to the following embodiment. In the following embodiment, constituent elements (element steps and the like are also included) are not essential except when the constituent elements are particularly specified as being so. This is the same for numerical values and the ranges thereof, and the numerical values and the ranges do not limit the present invention.

In the present disclosure, the term “step” includes not only a step independent of other steps but also a step when the purpose of the step is achieved even when the step cannot be clearly distinguished from other steps.

In the present disclosure, a numerical range indicated using “to” includes numerical values before and after “to” as a minimum value and a maximum value.

In a numerical range described in a stepwise manner in the present disclosure, an upper limit value or a lower limit value mentioned in one numerical range may be replaced with an upper limit value or a lower limit value in another numerical range mentioned in a stepwise manner. Further, in a numerical range mentioned in the present disclosure, an upper limit value or a lower limit value in the numerical range may be replaced with a value shown in an example.

Each component in the present disclosure may include a plurality of types of corresponding materials. In a case where a plurality of types of materials corresponding to each component are included in a composition, a percentage content or content of each component means a total percentage content or content of a plurality of types of materials that are present in a composition unless otherwise noted.

In the present disclosure, a plurality of types of particles corresponding to each component may be contained. In a case where a plurality of types of particles corresponding to each component are present in a composition, a particle size of each component means a value for a mixture of the plurality of types of particles that are present in the composition unless otherwise noted.

In the present disclosure, the term “layer” is used not only in a case where the layer is formed in the entirety of a region when the region in which the layer is present is observed, but also in a case where the layer is formed in only a portion of the region.

When the embodiment is described in the present disclosure with reference to the drawings, a configuration of the embodiment is not limited to the configurations shown in the drawings. In addition, the sizes of members in the drawing are conceptual, and relative relationships between the sizes of the members are not limited thereto.

<Heat Radiating Material (First Embodiment)>

A heat radiation material in the present embodiment is a heat radiation material that includes metal particles and a resin and includes a region in which the metal particles arranged in a surface direction are present at a relatively high density therein.

In the present disclosure, the “inside” of a heat radiation material means a portion other than the surface of the heat radiation material.

In the present disclosure, a “surface direction” means a direction along a principal surface of a heat radiation material, and a “region in which metal particles are present at a relatively high density” means a region in which metal particles are present at a higher density as compared to other regions of the heat radiation material.

The heat radiation material having the above-described configuration exhibits an excellent heat radiation effect in a case where the heat radiation material is attached to a heat generator. The reason for this is not necessarily clear, but it is thought to be as follows.

In the above-described heat radiation material, a region in which metal particles arranged in a surface direction are present at a relatively high density (hereinafter, also referred to as a metal particle layer) is formed inside the heat radiation material. The metal particle layer has a minute uneven structure caused by the shape of metal particles on the surface thereof. When heat is transferred to the metal particle layer from the heat generator, surface plasmon resonance occurs, and thus it is thought that a wavelength range of electromagnetic waves which are radiated changes. As a result, for example, a radiation rate of electromagnetic waves in a wavelength range in which there is hardly any absorption thereof by a resin is relatively increased, heat storage by a resin is reduced, and thus it is thought that heat radiation performance is improved.

The “resin” as mentioned herein may include both a resin contained in a heat radiation material and a resin disposed outside the heat radiation material (a resin case or the like).

As described above, the metal particle layer included in the heat radiation material has a function of changing a wavelength spectrum of electromagnetic waves radiated by the heat radiation material. In general, resins tend to barely absorb (readily transmit) electromagnetic waves in a relatively low wavelength infrared region (for example, 2 μm to 10 μm). Thus, in all embodiments, a metal particle layer included in a heat radiation material has a function of changing a wavelength range of electromagnetic waves radiated by the heat radiation material so that a radiation rate of electromagnetic waves in the infrared region increases.

Whether or not the metal particle layer has the above-described function can be determined according to whether or not an absorption wavelength spectrum measured using a Fourier transform infrared spectrophotometer changes. Specifically, it is possible to confirm whether or not a metal particle layer has the above-described function by comparing an absorption wavelength spectrum of a sample manufactured under the same conditions as those of the heat radiation material of the present embodiment, except that a metal particle layer is not included, with an absorption wavelength spectrum of the heat radiation material of the present embodiment.

In the heat radiation material of the present embodiment, surface plasmon resonance occurs due to forming a metal particle layer inside the heat radiation material. For this reason, it is possible to generate surface plasmon resonance by a simple method as compared to, for example, a method for generating surface plasmon resonance by processing the surface of a metal plate to form a minute uneven structure.

The form of the metal particle layer is not particularly limited as long as the form may generate surface plasmon resonance. For example, a clear boundary may be or may not be formed between the metal particle layer and another region. In addition, the metal particle layer may be continuously or discontinuously (including having a pattern shape) present in the heat radiation material. Metal particles contained in the metal particle layer may or may not be in contact with adjacent particles.

The thickness of the metal particle layer (the thickness of a portion having a minimum thickness in a case where the thickness is not fixed) is not particularly limited. For example, the thickness may be in a range of 0.1 μm to 100 μm. The thickness of the metal particle layer can be adjusted, for example, according to the amount of metal particles contained in the metal particle layer, the size of a metal particle, or the like.

A proportion of the metal particle layer in the whole heat radiation material is not particularly limited. For example, a ratio of the thickness of the metal particle layer to the whole heat radiation material may be in a range of 0.1% to 99% or may be in a range of 1% to 50%.

The density of metal particles in the metal particle layer is not particularly limited in a state where surface plasmon resonance may occur. For example, when the metal particle layer (or the heat radiation material) is observed from in front (a principal surface of the heat radiation material), a proportion of metal particles in an observation surface is preferably 50% or more, more preferably 75% or more, and still more preferably 90% on an area basis.

In the present disclosure, the “observation surface when the metal particle layer is observed from in front” means a surface which is observed from a direction (a thickness direction of the heat radiation material) perpendicular to a direction (a surface direction of the heat radiation material) in which metal particles are arranged. The proportion can be calculated, for example, from an electron microscope image using image processing software.

The position of metal particles (metal particle layer) in the heat radiation material is not particularly limited as long as the metal particles are formed inside the heat radiation material. For example, the metal particles may be positioned at the center in the thickness direction of the heat radiation material. In addition, the heat radiation material may be positioned closer to a surface facing the heat generator, or the heat radiation material may be positioned closer to a surface opposite to the surface facing the heat generator.

In the present disclosure, the “metal particle” means a particle in which at least a portion of the surface thereof is a metal, and the inside of the particle may be or may not be a metal. From the viewpoint of improving heat radiation performance through thermal conduction, it is preferable that the inside of the particle be a metal.

In a case where at least a portion of the surface of the metal particle is a metal, a case where a material other than a metal such as a resin or a metal oxide is present around the metal particles is also included when electromagnetic waves from the outside can reach the surfaces of the metal particles.

Examples of a metal contained in the metal particles include copper, aluminum, nickel, iron, silver, gold, tin, titanium, chromium, palladium, and the like. The number of types of metal contained in the metal particles may only one or may be two or more. In addition, the metal may be a single substance or may be in an alloy state.

The shape of the metal particle is not particularly limited as long as a desired uneven structure can be formed in the surface of the metal particle layer. Specific examples of the shape of the metal particle include a spherical shape, a flake shape, an acicular shape, a rectangular shape, a cubic shape, a tetrahedral shape, a hexahedral shape, a polyhedral shape, a cylindrical shape, a hollow shape, a three-dimensional acicular structure extending in different four axial directions from a core part, and the like. Among these, a spherical shape or a shape close to a spherical shape is preferable.

The size of the metal particles is not particularly limited. For example, a volume average particle diameter of the metal particles is preferably in a range of 0.1 μm to 30 μm. When the volume average particle diameter of the metal particles is 30 μm or less, there is a tendency for electromagnetic waves to be sufficiently radiated (particularly, infrared light having a relatively low wavelength) contributing to an improvement in heat radiation performance. When the volume average particle diameter of the metal particles is 0.1 μm or more, a cohesive force of the metal particles is reduced, and the metal particles tend to be easily arranged evenly.

The volume average particle diameter of the metal particles may be set in consideration of the types of materials other than the metal particles which are used for the heat radiation material. For example, as the volume average particle diameter of the metal particles becomes smaller, the period of the uneven structure formed in the surface of the metal particle layer decreases, and a wavelength at which surface plasmon resonance occurring in the metal particle layer is maximized is reduced. An absorption rate of electromagnetic waves by the metal particle layer is a maximum at a wavelength at which surface plasmon resonance is maximized. Thus, when a wavelength at which surface plasmon resonance occurring in the metal particle layer is maximized is reduced, a wavelength at which an absorption rate of electromagnetic waves by the metal particle layer is maximized is reduced, and a radiation rate of electromagnetic waves in the wavelength tends to increase according to Kirchhoff's law. For this reason, it is possible to convert a radiation wavelength of the metal particle layer to a wavelength range at which there is hardly any absorption by a resin contained in a heat radiation material by appropriately selecting the volume average particle diameter of the metal particles, and thus the heat radiation performance tends to be further improved.

The volume average particle diameter of the metal particles contained in the metal particle layer may be 10 μm or less, may be 5 μm or less, or may be 3 μm or less. When the volume average particle diameter of the metal particles is in the above-described ranges, a wavelength range of electromagnetic waves that are radiated can be converted to a low wavelength range hardly absorbed by a resin (for example, 6 μm or less). Thereby, heat storage by a resin is reduced, and thus it is possible to further improve the heat radiation performance.

In the present disclosure, the volume average particle diameter of the metal particles is a particle diameter (D50) at a cumulative 50% from a small diameter end in a volume-based particle size distribution curve obtained by a laser diffraction scattering method.

From the viewpoint of effectively controlling absorption of electromagnetic waves by the metal particle layer or a radiation wavelength, it is preferable that a variation in the particle diameter of the metal particles contained in the metal particle layer be small. It becomes easy to form an uneven structure having periodicity on the surface of the metal particle layer by reducing variation in the particle diameter of the metal particles, and surface plasmon resonance tends to easily occur.

In a case where a particle diameter (D10), for example, at a cumulative 10% from a small diameter end in a volume-based particle size distribution curve is assumed to be A (μm), and a particle diameter (D90) when integration from a small diameter end is set to 90% is assumed to be B (μm), a variation in the particle diameter of the metal particle is preferably set such that the value of A/B is approximately 0.3 or more, is more preferably set such that the value of A/B is approximately 0.4 or more, and is still more preferably set such that the value of A/B is approximately 0.6 or more.

The type of resin contained in the heat radiation material is not particularly limited, and can be selected from known thermosetting resins, thermoplastic resins, ultraviolet curing resins, and the like. Specifically, examples of the resin include a phenolic resin, an alkyd resin, an amino alkyd resin, a urea resin, a silicone resin, a melamine urea resin, an epoxy resin, a polyurethane resin, an unsaturated polyester resin, a vinyl acetate resin, an acrylic resin, a rubber chloride resin, a vinyl chloride resin, a fluororesin, and the like. Among these, from the viewpoint of heat resistance, availability, and the like, an acrylic resin, an unsaturated polyester resin, an epoxy resin, and the like are preferably used. The number of types of resins contained in the heat radiation material may be only one or may be two or more.

The heat radiation material may contain materials other than a resin and metal particles. For example, the heat radiation material may contain ceramic particles, additives and the like.

For example, it is possible to further improve a heat radiation effect by the heat radiation material containing ceramic particles. Specific examples of the ceramic particles include particles such as those of boron nitride, aluminum nitride, aluminum oxide, magnesium oxide, titanium oxide, zirconia, iron oxide, copper oxide, nickel oxide, cobalt oxide, lithium oxide, and silicon dioxide. The number of types of ceramic particles contained in the metal particle layer may be only one or may be two or more. In addition, the surface thereof may be covered with a film constituted by a resin, an oxide, or the like.

The size and shape of the ceramic particles are not particularly limited. For example, the size and shape of the ceramic particles may be the same as the size and shape of the metal particles which are described above as preferred aspects.

When the heat radiation material contains an additive, it is possible to add a desired function to the heat radiation material or a material for forming the heat radiation material. Specific examples of the additive include a dispersant, a film-forming assistant, a plasticizer, a pigment, a silane coupling agent, a viscosity modifier, and the like.

The shape of the heat radiation material is not particularly limited, and can be selected according to the purpose or the like. Examples of the shape of the heat radiation material include a sheet shape, a film shape, a plate shape, and the like. Alternatively, the heat radiation material may be in the state of a layer formed by applying a material of the heat radiation material to a heat generator.

The thickness of the heat radiation material (the thickness of a portion having a minimum thickness in a case where the thickness is not fixed) is not particularly limited. For example, the thickness of the heat radiation material is preferably in a range of 1 μm to 500 μm, and is more preferably in a range of 10 μm to 200 μm. When the thickness of the heat radiation material is 500 μm or less, the heat radiation material does not easily become a heat insulating layer, and good heat radiation performance tends to be maintained. When the thickness of the heat radiation material is 1 μm or more, a function of the heat radiation material tends to be sufficiently obtained.

A wavelength region of electromagnetic waves that are absorbed or radiated by the heat radiation material is not particularly limited, but from the viewpoint of heat radiation properties, it becomes more preferable as an absorption rate or a radiation rate for each wavelength in a range of 3 μm to 30 μm at room temperature (25° C.) becomes closer to 1.0. Specifically, 0.8 or more is preferable, and 0.9 or more is more preferable.

An absorption rate or a radiation rate of electromagnetic waves can be measured by a radiation rate measuring device (for example, D and S AERD manufactured by Kyoto Electronics Co., Ltd.), a Fourier transform infrared spectrophotometer, or the like. It can be considered that an absorption rate and a radiation rate of electromagnetic waves are equal according to Kirchhoff s law.

A wavelength region of electromagnetic waves that are absorbed or radiated by the heat radiation material can be measured by a Fourier transform infrared spectrophotometer. Specifically, the transmissivity and reflexibility of each wavelength can be measured and calculated by the following equation.

An absorption rate(radiation rate)=1−Transmissivity−Reflexibility

The purpose of the heat radiation material is not particularly limited. For example, the heat radiation material may be attached to a location corresponding to a heat generator of electronic equipment so that the heat radiation material is used to radiate heat generated by the heat generator. In addition, the heat radiation material may be used to transfer heat generated by the heat generator to a heat radiator such as a metal plate or a heat sink.

It is preferable that the metal particle layer includes an uneven structure caused by metal particles on the surface thereof. When heat is transferred from the heat generator to the metal particle layer having an uneven structure caused by metal particles on the surface thereof, surface plasmon resonance occurs, and it is considered that a wavelength range of electromagnetic waves that are radiated changes. As a result, for example, a radiation rate of electromagnetic waves in a wavelength range not absorbed by the resin contained in the heat radiation material increases relatively, heat storage by the resin is suppressed, and thus it is considered that heat radiation performance is improved.

The heat radiation material may include a region 1, a region 2 and a region 3 satisfying the following (A) and (B) in this order.

(A) A total value of absorption of electromagnetic waves at wavelengths of 2 μm to 6 μm in the region 2)>a total value of absorption of electromagnetic waves at wavelengths of 2 μm to 6 μm in the region 1 and the region 3)

(B) A metal particle occupancy rate in the region 2>metal particle occupancy rates in the region 1 and the region 3

The heat radiation material having the above-described configuration exhibits an excellent heat radiation effect in a case where the heat radiation material is attached to the heat generator. The reason is not necessarily clear, but it can be considered as follows.

In general, a resin has a property of hardly absorbing short-wavelength infrared light and easily absorbing long-wavelength infrared light. For this reason, it is considered that heat storage by a resin is suppressed by increasing an absorption rate (that is, increasing the radiation rate) of electromagnetic waves in a wavelength range of 2 μm to 6 μm hardly absorbed by a resin, which leads to an improvement in heat radiation performance.

The heat radiation material having the above-described configuration solves the above-described problem by including the region 2 having a larger integrated value of absorption rates of electromagnetic waves in the wavelength range of 2 μm to 6 μm than those of the region 1 and the region 3.

A specific example of the region 2 is a layer (metal particle layer) which is configured to have a minute uneven structure formed of metal particles by containing a relatively large amount of metal particles and to exhibit a surface plasmon resonance effect.

A specific example of the region 1 and the region 3 is a layer (resin layer) containing a relatively large amount of resin.

The position of the region 2 is not particularly limited as along as the position is between the region 1 and the region 3, and the region 2 may be disposed at the center in the thickness direction of the heat radiation material, may be disposed on a side close to the heat generator, or may be disposed on a side close to a side opposite to the side facing the heat generator.

A clear boundary may be or may not be present between adjacent regions (for example, a metal particle occupancy rate changes in a thickness direction in a stepwise manner).

In the above-described configuration, the “metal particle occupancy rate” means a volume-based ratio of metal particles to the region. The “absorption rate of electromagnetic waves” can be measured in the same manner as the above-described absorption rate of electromagnetic waves of the heat radiation material.

The region 2 is disposed between the region 1 and the region 3, and thus a state where metal particles contained in the region 2 are arranged is maintained, which leads to a tendency for stable heat radiation performance to be obtained.

The materials contained in the region 1 and the region 3, the thicknesses thereof, and the like may be the same or different. For example, in a case where the region 1 is positioned on the heat generator side, it is possible to efficiently transfer heat to the region 1 by using a material having a high thermal conductivity and expect a further improvement in heat radiation performance.

<Method of Producing Heat Radiation Material>

A method for producing a heat radiation material of the present embodiment (first embodiment) includes a step of disposing metal particles on a first resin layer and a step of disposing a second resin layer on the metal particles in this order.

According to the above-described method, it is possible to produce a heat radiation material containing metal particles and a resin and having a structure in which the metal particles are unevenly distributed inside.

From the viewpoint of obtaining good heat radiation performance by causing surface plasmon resonance in metal particles, it is preferable that the metal particles form a metal particle layer included in the above-described heat radiation material. That is, it is preferable that metal particles satisfy details and preferred aspects of the metal particle layer included in the heat radiation material described above.

The first resin layer and the second resin layer that are used in the above-described method may be layers containing a resin contained in the above-described heat radiation material or may further contain ceramic particles, an additive, and the like contained in the above-described heat radiation material. The metal particles used in the above-described method may be metal particles contained in the above-described heat radiation material.

The materials and dimensions of the first resin layer and the second resin layer may be the same or different. From the viewpoint of workability, it is preferable that the layers be in a preformed state (a resin film or the like). From the viewpoint of securing adhesion between the resin layers and adhesion to metal particles or an adherend, both or any one of the first resin layer and the second resin layer may have adhesiveness on both sides or one side thereof.

From the viewpoint of suppressing uneven distribution of metal particles, it is preferable that the surface of the first resin layer on which the metal particles are disposed have adhesiveness. When the surface of the first resin layer on which the metal particles are disposed has adhesiveness, the movement of the metal particles when the metal particles are disposed on the first resin layer is suppressed appropriately, which leads to a tendency for uneven distribution of the metal particles to be suppressed.

A method of disposing metal particles on the first resin layer is not particularly limited. An example of the method is a method of disposing metal particles or a composition containing the metal particles using a brush, a sieve, an electrospray, a coater, an inkjet device, a screen printing device, or the like. In a case where the metal particles form aggregates, it is preferable to perform a process of crushing the aggregates before disposing metal particles.

A method of disposing the second resin layer on the metal particles disposed on the first resin layer is not particularly limited. An example of the method is a method of laminating a film-shaped second resin layer while heating the second resin layer as necessary.

In the method, a heat radiation material may be produced independently, or a heat radiation material may be formed on the surface of a heat generator. An example of a method of forming the heat radiation material on the surface of the heat generator is a method of disposing the first resin layer on the surface of the heat generator before a step of disposing metal particles on the first resin layer.

A method for producing a heat radiation material of the present embodiment (second embodiment) includes a step of disposing metal particles on a flat surface, a step of disposing a first resin layer on the metal particles to obtain a laminated body, a step of separating the laminated body from the flat surface, and a step of disposing a second resin layer on the metal particles in this order.

According to the above-described method, it is possible to produce a heat radiation material containing metal particles and a resin and having a structure in which the metal particles are unevenly distributed inside.

As details and preferred aspects of the materials and the methods used in the above-described method, details and preferred aspects of the materials and the methods described in the method according to the first embodiment can be referred to.

<Heat Radiating Material Kit>

A heat radiation material kit of the present embodiment is a heat radiation material kit that includes metal particles and a resin and is used to produce the above-described heat radiation material.

Details and preferred aspects of the metal particles, the resin, and other components contained in the heat radiation material kit are the same as the details and the preferred aspects of the metal particles, the resin, and the other components described in the above-described heat radiation material and producing method therefor.

The metal particles may be in their intact state or may be in a state of a composition containing a dispersion medium or the like.

The resin may be in a preformed state (a resin film or the like) or may not be formed.

A method for producing a heat radiation material using a heat radiation material kit is not particularly limited. For example, the above-described method for producing a heat radiation material may be used.

<Heating Generator>

A heat generator of the present embodiment includes the heat radiation material according to the above-described embodiment.

The type of heat generator is not particularly limited. Examples the type include an integrated circuit (IC) included in electronic equipment, an electronic component such as a semiconductor element, a heat pipes, and the like.

An aspect in which a heat radiation material is attached to a heat generator is not particularly limited. For example, an adhesive heat radiation material may be directly attached, or may be attached through an adhesive material or the like.

When a heat radiation material is attached to a heat generator, the heat radiation body may be attached such that the position of a metal particle layer in the heat radiation material is close to the heat generator side or the position of the metal particle layer in the heat radiation material is close to a side opposite to the heat generator.

The heat generator may include a heat radiator as necessary. In this case, it is preferable that a heat radiation material be interposed between the main body of the heat generator and the heat radiator. Excellent heat radiation performance is achieved by the heat radiation material being interposed between the main body of the heat generator and the heat radiator. Examples of the heat radiator include a plate formed of a metal such as aluminum, iron, or copper, a heat sink, and the like.

The portion of the main body to which the heat radiation material is attached may be or may not be a flat surface. In a case where the portion of the main body to which the heat radiation material is attached is not a flat surface, the heat radiation material may be attached using a heat radiation material having flexibility.

### EXAMPLES

Hereinafter, the present disclosure will be described in more detail with reference to examples. However, the present disclosure is not limited to details described in the following examples.

### Example 1

A metal particle layer is formed by placing 5 g of copper particles (a volume average particle diameter: 1.6 μm) crushed using a vibration agitator on one side of a substrate-less acrylic resin double-sided tape (100 mm×100 mm, thickness of 25 μm), uniformly spreading the copper particles using a commercially available brush, and removing surplus copper particles using an air duster. The ratio of metal particles when the metal particle layer is observed from in front is 80% or more on an area basis.

Next, an acrylic resin film (Tg: 75° C., a molecular weight: 30,000, 100 mm×100 mm, a thickness of 25 μm) formed on a polyethylene terephthalate (PET) substrate is laminated on the metal particle layer while heating the acrylic resin film at 80° C. Thereafter, the PET substrate is peeled off, and the surface on the double-sided tape side is attached to an aluminum plate having a size of 50 mm×80 mm and a thickness of 2 mm to manufacture a sample.

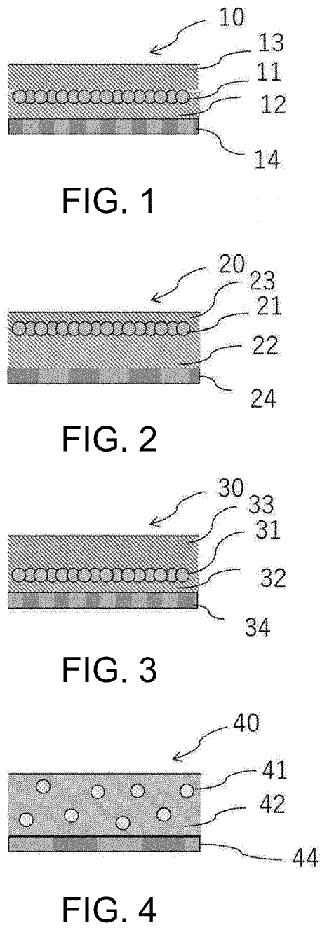

A schematic cross-sectional view of the manufactured sample is shown in FIG. 1. As illustrated in FIG. 1, a sample 10 includes a metal particle layer 11 formed by copper particles aggregating in the center in the thickness direction, and a resin layer 12 and a resin layer 13 which are disposed on both sides of the metal particle layer 11. In addition, the resin layer 12 side is attached to an aluminum plate 14.

A heat radiation rate of the manufactured sample (an aluminum plate is included) is measured at room temperature (25° C.) (a measurement wavelength range: 3 μm to 30 μm) using a radiation rate measuring device (D and S AERD manufactured by Kyoto Electronics Co., Ltd.). A radiation rate of the sample in Example 1 is 0.9.

### Example 2

A sample of a heat radiation material is manufactured in the same manner as Example 1 except that the thickness of an acrylic resin film formed on a PET substrate is changed to 10 μm.

A schematic cross-sectional view of the manufactured sample is shown in FIG. 2. As shown in FIG. 2, a sample 20 includes a metal particle layer 21 formed by copper particles aggregating closer to the side of a surface opposite to an aluminum plate 24 than the center in the thickness direction, and a resin layer 22 and a resin layer 23 which are disposed on both sides of the metal particle layer 21.

### Example 3

A sample of a heat radiation material is manufactured in the same manner as Example 1 Except that the thickness of an acrylic resin double-sided tape is changed to 10 μm.

A schematic cross-sectional view of the manufactured sample is shown in FIG. 3. As shown in FIG. 3, a sample 30 includes a metal particle layer 31 formed by copper particles aggregating closer to an aluminum plate 34 side than the center in the thickness direction, and an acrylic resin layer 32 and an acrylic resin layer 33 which are disposed on both sides of the metal particle layer 31.

### Comparative Example 1

30% by mass of butyl acetate is mixed with 100% by mass of an acrylic resin to prepare a composition having an adjusted viscosity. This composition is spray-coated on the entire surface of an aluminum plate having a size of 50 mm×80 mm and a thickness of 2 mm using a spray coating apparatus to form a composition layer. This composition layer is naturally dried and cured by heating at 60° C. for 30 minutes to prepare a sample having a film thickness of 30 μm.

A radiation rate of the sample in Comparative Example 1 which is measured in the same manner as in Example 1 is 0.7.

### Comparative Example 2

The same composition as that in Comparative Example 1 is spray-coated on the entire surface of an aluminum plate having a size of 50 mm×80 mm and a thickness of 2 mm using a spray coating apparatus to form a composition layer. This composition layer is naturally dried and cured by heating at 60° C. for 30 minutes to prepare a sample having a film thickness of 100 μm.

A radiation rate of the sample in Comparative Example 2 which is measured in the same manner as in Example 1 is 0.9.

### Comparative Example 3

A commercially available heat radiating paint containing 95% by volume of an acrylic resin and 5% by volume of silicon dioxide particles (a volume average particle diameter: 2 μm) is spray-coated on an aluminum plate having a size of 50 mm×80 mm and a thickness of 2 mm using a spray coating apparatus to form a composition layer. This composition layer is naturally dried and cured by heating at 60° C. for 30 minutes to prepare a sample having a film thickness of 30 μm.

A schematic cross-sectional view of the manufactured sample is shown in FIG. 4. As shown in FIG. 4, a sample 40 contains silicon dioxide particles 41 and a resin 42, and has a structure in which the silicon dioxide particles 41 are dispersed without being unevenly distributed at a specific portion in the resin 42.

A radiation rate of the sample in Comparative Example 3 which is measured in the same manner as in Example 1 is 0.81.

<Comparison of Absorption Wavelength Spectrum>

Absorption wavelength spectrums of the samples (an aluminum plate is included) manufactured in Example 1, Comparative Example 1, and Comparative

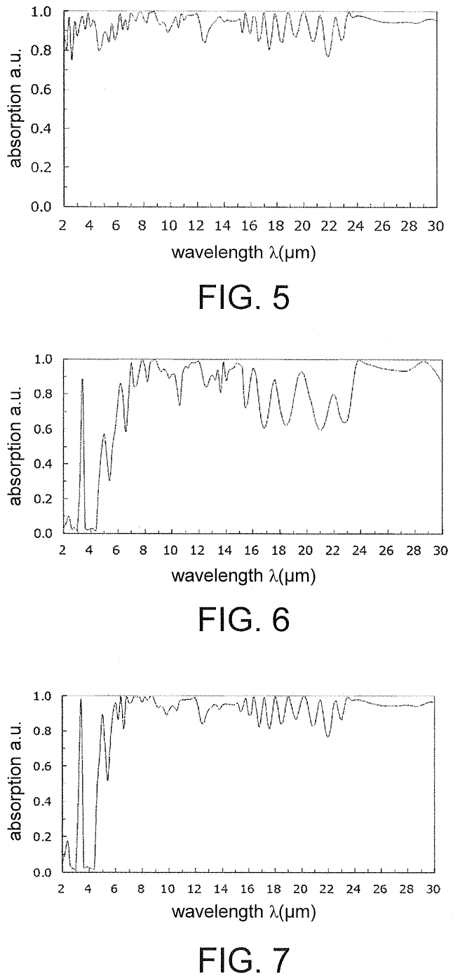

Example 2 are measured by a Fourier transform infrared spectrophotometer. The obtained absorption wavelength spectrums are shown in FIGS. 5, 6, and 7. In Example 1 (FIG. 5) including a metal particle layer, it can be confirmed that absorption efficiency is increased particularly in a wavelength range of 10 μm or less, as compared with Comparative Example 1 (FIG. 6) and Comparative Example 2 (FIG. 7) which do not include a metal particle layer.

Compared to the sample in Comparative Example 1, the sample in Comparative Example 2 has an increased absorption efficiency in a wavelength range of 8 μm or more due to an increase in the thickness of the sample, and thus it can be understood that a radiation rate is higher than that of the sample in Comparative Example 1. On the other hand, it can be understood that absorption efficiency in a wavelength range of 8 μm or less hardly changes.

<Evaluation of Heat Radiation Performance>

Heat radiation performance is evaluated by the following method using the samples manufactured in the examples and the comparative examples. Results are shown in Table 1.

A commercially available planar heat generator (polyimide heater) is sandwiched between a pair of aluminum plates (50 mm×80 mm, a thickness of 2 mm). As one of the aluminum plates, the samples manufactured in the examples and the comparative examples are used. A K thermocouple is bonded to the surface of the aluminum plate using an aluminum solder.

In this state, the aluminum plate is placed at the center of a constant temperature bath which is set at 25° C., and a change in the surface temperature of the aluminum plate is measured. At this time, an output of the heater is set such that the surface temperature of the aluminum plate which is not the sample is 100° C. Since the heater generates a fixed amount of heat, the higher a heat radiation effect of the sample, the lower the surface temperature of the aluminum plate. That is, it can be said that the lower the surface temperature of the sample, the higher the heat radiation effect. Table 1 shows the measured surface temperature (maximum temperature) of the sample.

TABLE 1

| | Comparative | Comparative | Comparative | | | |
|---|---|---|---|---|---|---|
| | Example 1 | Example 2 | Example 3 | Example 1 | Example 2 | Example 3 |
| Maximum | 85 | 80 | 78 | 70 | 70 | 70 |
| temperature | | | | | | |
| (° C.) | | | | | | |

As shown in Table 1, in Comparative Example 1 and Comparative Example 2 using a sample including a composition layer formed of only a resin, the surface temperatures are reduced to 85° C. and 80° C., respectively, as compared to the surface temperature 100° C. of the aluminum plate which is not the sample, but the reduction effect is small as compared to the examples. It is considered that this is because the samples do not include a metal particle layer, so that a heat radiation effect due to the transfer of radiative heat is smaller than that in the examples.

In Comparative Example 3 using the sample in which silicon dioxide particles are uniformly dispersed in a resin, the surface temperature is reduced to 78° C., but the reduction effect is smaller than that in the examples. It is considered that this is because the silicon dioxide particles are uniformly dispersed in a resin, so that the effect of amplifying heat radiation performance based on surface plasmon resonance is not sufficiently obtained. Since silicon dioxide particles and copper particles have the same heat radiation characteristics, it is considered that the results as shown in Comparative Example 3 are obtained also in a case where copper particles are dispersed in a resin.

### Example 7

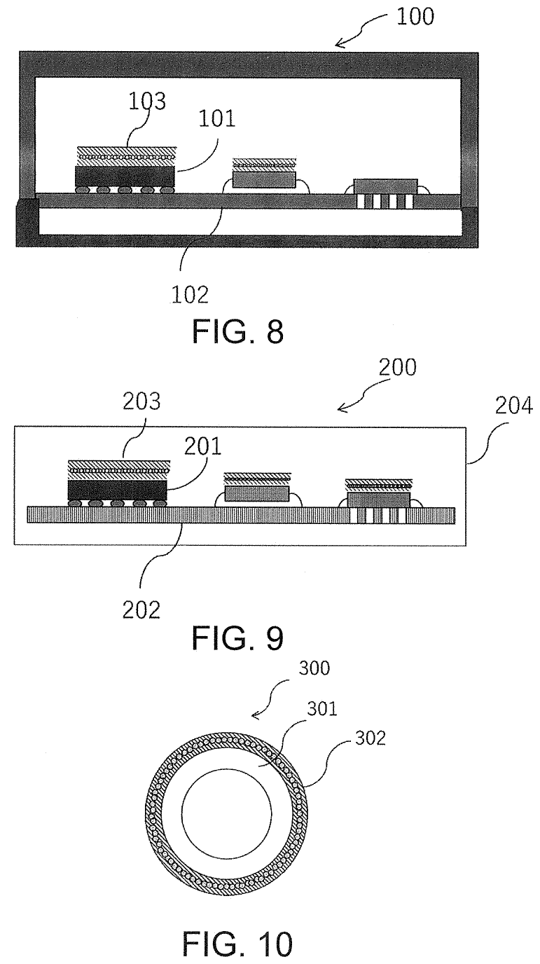

The sample manufactured in Example 1 is attached to an electronic component (heat generator) of electronic equipment as shown in FIG. 8 to examine a temperature reduction effect.

An electronic equipment 100 shown in FIG. 8 includes an electronic component 101 and a circuit board 102 on which the electronic component is mounted. A resin layer 12 side of a sample 103 (an aluminum plate is excluded) manufactured in Example 1 is attached to an upper portion of the electronic component 101. When the electronic equipment is operated, the temperature of the electronic component 101 is reduced from 125° C. (no sample) to 95° C.

### Example 8

The sample manufactured in Example 1 is attached to an electronic component (heat generator) of electronic equipment as shown in FIG. 9 to examine a temperature reduction effect.

Electronic equipment 200 shown in FIG. 9 includes an electronic component 201 and a circuit board 202 on which the electronic component is mounted. Further, the periphery of the electronic component 201 is sealed with a resin 204. A resin layer 12 side of a sample 203 (an aluminum plate is excluded) manufactured in Example 1 is attached to an upper portion of the electronic component 201. When the electronic equipment is operated, the temperature of the electronic component 201 is reduced from 155° C. (no sample) to 115° C.

### Example 9

The sample manufactured in Example 1 is attached to a heat pipe (heat generator) as shown in FIG. 10 to examine a temperature reduction effect.

A heat pipe 300 shown in FIG. 10 is a stainless steel pipe 301 (a diameter of 32 mm), and a resin layer 12 side of a sample 302 (an aluminum plate is excluded) manufactured in Example 2 is attached to the periphery thereof. When 90° C. water is supplied into the heat pipe, the surface temperature is reduced from 85° C. (no sample) to 68° C.

All documents, patent applications, and technical standards described in the present specification are invoked and incorporated in the present specification to the same extent as in a case where individual documents, patent applications, and technical standards are specifically and individually stated to be incorporated by reference.

1. A heat radiation material comprising:
metal particles; and
a resin,
wherein a region in which the metal particles arranged in a surface direction are present at a relatively high density is provided inside the heat radiation material.

2. The heat radiation material according to claim 1, wherein a proportion of the metal particles in an observation surface is 50% or more on an area basis when the region is observed from in front.

3. The heat radiation material according to claim 1, wherein the region has a function of changing an absorption wavelength spectrum of the heat radiation material which is measured using a Fourier transform infrared spectrophotometer.

4. The heat radiation material according to claim 1, wherein the region is provided at a center in a thickness direction of the heat radiation material.

5. The heat radiation material according to claim 1, wherein the region is provided close to a side of a surface facing a heat generator.

6. The heat radiation material according to claim 1, wherein the region is provided close to a side of a surface opposite to a surface facing a heat generator.

7. The heat radiation material according to claim 1, wherein a thickness of the region is in a range of 0.1 μm to 100 μm.

8. The heat radiation material according to claim 1, wherein a ratio of a thickness of the region to a whole thickness of the heat radiation material is in a range of 0.1% to 99%.

9. The heat radiation material according to claim 1, wherein the region has an uneven structure derived from the metal particles on a surface thereof.

10. The heat radiation material according to claim 1, wherein a region 1, a region 2, and a region 3 are provided in this order, and
the region 1, the region 2, and the region 3 are satisfying the following (A) and (B):
(A) a total value of absorption of electromagnetic waves at wavelengths of 2 μm to 6 μm in the region 2>a total value of absorption of electromagnetic waves at wavelengths of 2 μm to 6 μm in the region 1 and the region 3, and
(B) a metal particle occupancy rate in the region 2>metal particle occupancy rates in the region 1 and the region 3.

11. A method for producing a heat radiation material which comprises following steps in the following order, the steps comprising:
a step of disposing metal particles on a first resin layer; and
a step of disposing a second resin layer on the metal particles.

12. A heat radiation material kit which is used to produce the heat radiation material according to claim 1, the heat radiation material kit comprising:
metal particles; and
a resin.

13. A heat generator comprising the heat radiation material according to claim 1.

14. The heat radiation material according to claim 2, wherein the region has a function of changing an absorption wavelength spectrum of the heat radiation material which is measured using a Fourier transform infrared spectrophotometer.

15. The heat radiation material according to claim 2, wherein the region is provided at a center in a thickness direction of the heat radiation material.

16. The heat radiation material according to claim 3, wherein the region is provided at a center in a thickness direction of the heat radiation material.

17. The heat radiation material according to claim 2, wherein the region is provided close to a side of a surface facing a heat generator.

18. The heat radiation material according to claim 3, wherein the region is provided close to a side of a surface facing a heat generator.

19. The heat radiation material according to claim 2, wherein the region is provided close to a side of a surface opposite to a surface facing a heat generator.

20. The heat radiation material according to claim 3, wherein the region is provided close to a side of a surface opposite to a surface facing a heat generator.
